(19) United States
(12) Patent Application Publication
(10) Pub. No.: US 2019/0181276 A1
(43) Pub. Date: Jun. 13, 2019

(54) SOLAR CELL

(71) Applicant: Samsung SDI Co., Ltd., Yongin-si (KR)

(72) Inventors: Sang Hee PARK, Suwon-si (KR); Sung Il MOON, Suwon-si (KR); Kyoung Jin HA, Suwon-si (KR)

(21) Appl. No.: 16/002,026

(22) Filed: Jun. 7, 2018

(30) Foreign Application Priority Data
Dec. 8, 2017 (KR) 10-2017-0168656

(51) Int. Cl. H01L 31/0224; H01B 1/22

(52) U.S. Cl. CPC H01L 31/022425; H01B 1/22

(57) ABSTRACT

A solar cell includes a silicon substrate and an electrode on the silicon substrate. The silicon substrate includes at least 5 raised portions having a cross-sectional height (h) of about 50 nm or more per 5 μm length. The electrode is formed from a composition for solar cell electrodes having a water contact angle of about 15° to about 60°.

### CROSS-REFERENCE TO RELATED APPLICATION

Korean Patent Application 10-2017-0168656, filed on Dec. 8, 2017, in the Korean Intellectual Property Office, and entitled: “Solar Cell,” is incorporated by reference herein in its entirety.

### BACKGROUND

### 1. Field

Embodiments relate to a solar cell.

### 2. Description of the Related Art

Solar cells generate electricity using the photovoltaic effect of a PN junction which converts photons of sunlight into electricity. In a solar cell, front and rear electrodes are formed on upper and lower surfaces of a semiconductor wafer or substrate having a PN junction, respectively. Then, the photovoltaic effect at the PN junction is induced by sunlight entering the semiconductor wafer and electrons generated by the photovoltaic effect at the PN junction provide electric current to the outside through the electrodes. The electrodes of the solar cell are formed on the wafer by applying, patterning, and baking a composition for solar cell electrodes.

### SUMMARY

Embodiments are directed to a solar cell including a silicon substrate and an electrode on the silicon substrate. The silicon substrate includes at least 5 raised portions having a cross-sectional height (h) of about 50 nm or more per 5 μm length. The electrode is formed from a composition for solar cell electrodes having a water contact angle of about 15° to about 60°.

The composition for solar cell electrodes may include about 60 wt % to about 95 wt % of a conductive powder, about 0.1 wt % to about 20 wt % of a glass frit, about 0.1 wt % to about 15 wt % of an organic binder, about 0.1 wt % to about 5 wt % of a surface tension modifier, and about 0.1 wt % to about 20 wt % of a solvent.

The glass frit may include at least one elemental metal of tellurium (Te), lithium (Li), zinc (Zn), bismuth (Bi), lead (Pb), sodium (Na), phosphorus (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

The surface tension modifier may include at least one of a silicone-based additive, an amide-based additive, and a fatty acid-based surfactant.

The solvent may include at least one of hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, methylethylketone, benzyl alcohol, γ-butyrolactone, ethyl lactate, texanol, and diethylene glycol dibutyl ether.

The organic binder may include at least one of ethyl hydroxyethyl cellulose, nitrocellulose, a blend of ethyl cellulose and phenol resins, an alkyd resin, a phenol resin, an acrylate ester resin, a xylene resin, a polybutane resin, a polyester resin, a urea resin, a melamine resin, a vinyl acetate resin, wood rosin, a polymethacrylate of an alcohol, polyvinyl butyrate, and polyvinyl acetal.

The composition for solar cell electrodes may further include at least one additive, the at least one additive including at least one of a dispersant, a thixotropic agent, a plasticizer, a viscosity stabilizer, an anti-foaming agent, a pigment, a UV stabilizer, an antioxidant, and a coupling agent.

### BRIEF DESCRIPTION OF THE DRAWINGS

Features will become apparent to those of skill in the art by describing in detail exemplary embodiments with reference to the attached drawings in which:

FIG. 1 illustrates a schematic view of a solar cell according to an embodiment.

FIG. 2 illustrates a view illustrating the definition of a raised portion.

FIG. 3 illustrates an electron microscope image showing a raised portion of a solar cell.

FIG. 4 illustrates a view depicting the measurement of a water contact angle of a composition.

FIG. 5 illustrates an electron microscope image of Comparative Example 3 (a surface of a typical substrate).

FIG. 6 illustrates an electron microscope image of a surface of a substrate according to an Example.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present.

Unless stated otherwise, a margin of error is considered in analysis of components.

As used herein, the term “metal oxide” may refer to one metal oxide or a plurality of metal oxides.

Further, “X to Y”, as used herein to represent a range of a certain value, means “greater than or equal to X and less than or equal to Y”.

As used herein, the phrase “a substrate has a raised portion having a height (h) of 50 nm or more” indicates that the portion is higher than the surrounding surface and has a diameter of 500 nm or less, and that a vertical distance from the summit of the portion to a line connecting both sides of the portion is about 50 nm or more in a sectional view of the silicon substrate (see FIG. 2). FIG. 3 illustrates a sectional image of a silicon substrate as an aid to defining a raised portion.

Solar Cell

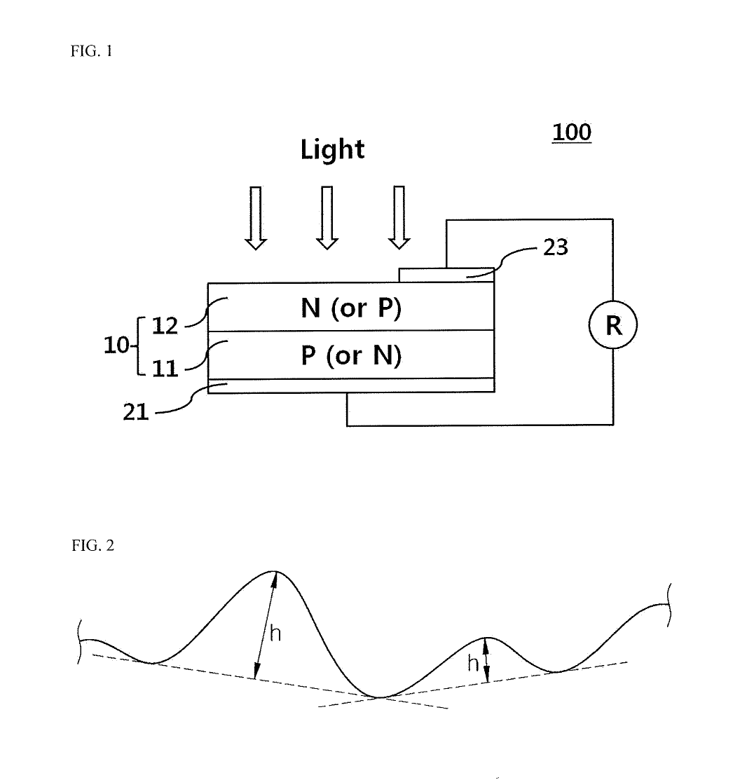

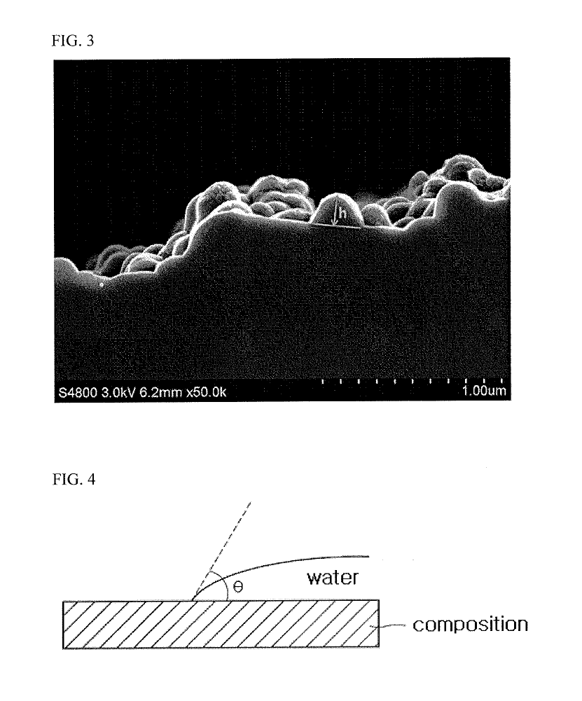

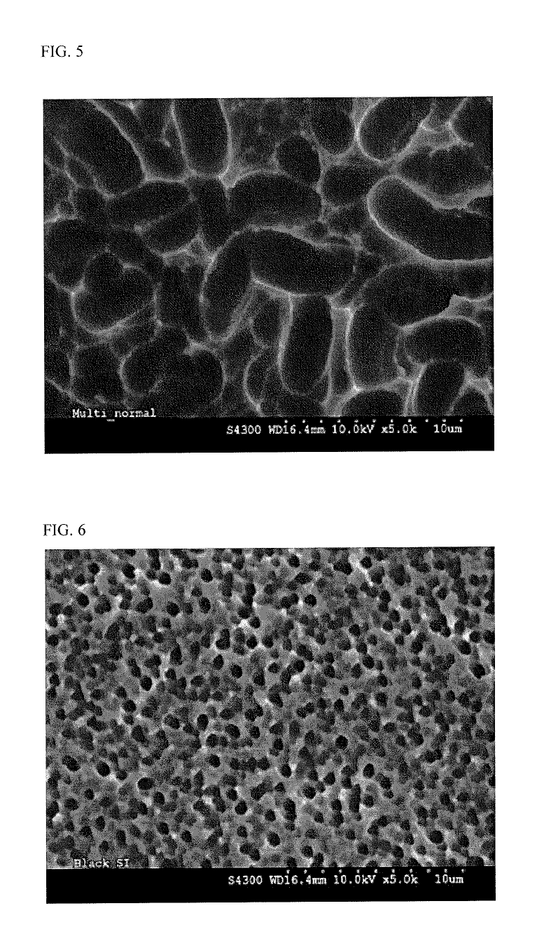

A solar cell according to an embodiment will be described with reference to FIG. 1, which illustrates a schematic view of a solar cell.

The solar cell 100 according to this embodiment may include a silicon substrate 10 and an electrode formed on the silicon substrate 10. For example, the solar cell may include a front electrode 23 formed on a front surface of the silicon substrate 10. The silicon substrate 10 may be a substrate with a PN junction formed thereon. A rear electrode 21 may be formed on a back surface of the silicon substrate 10. For example, the silicon substrate 10 may include a semiconductor substrate 11 and an emitter 12. As an example, the silicon substrate 10 may be a substrate prepared by doping one surface of a p-type semiconductor substrate 11 with an n-type dopant to form an n-type emitter 12. In some implementations, the substrate 10 may be a substrate prepared by doping one surface of an n-type semiconductor substrate 11 with a p-type dopant to form a p-type emitter 12. The semiconductor substrate 11 may be either a p-type substrate or an n-type substrate. The p-type substrate may be a semiconductor substrate 11 doped with a p-type dopant, and the n-type substrate may be a semiconductor substrate 11 doped with an n-type dopant.

In the descriptions of the silicon substrate 10, the semiconductor substrate 11 and the like herein, a surface of the substrate through which light enters the substrate is referred to as a “front surface” (or “light receiving surface”). A surface of the substrate opposite the front surface is referred to as a “back surface.”

In an embodiment, the semiconductor substrate 11 may be formed of crystalline silicon or a compound semiconductor. The crystalline silicon may be monocrystalline or polycrystalline. As an example, a silicon wafer may be used as the crystalline silicon.

The p-type dopant may be a material including a group III element such as boron, aluminum, or gallium. The n-type dopant may be a material including a group V element, such as phosphorus, arsenic or antimony.

The rear electrode 21 and/or the front electrode 23 may be fabricated using a composition for solar cell electrodes described below. As an example, the rear electrode and/or the front electrode may be fabricated through a process in which the composition for solar cell electrodes is deposited on the substrate by printing, followed by baking.

The solar cell 100 according to this embodiment may include the silicon substrate 10 and the electrode formed on the substrate 10, wherein the silicon substrate may be formed with 5 or more, or, for example 5 to 100, or, for example, 5 to 50 raised portions having a height (h) of about 50 nm or more per 5 μm length in sectional view.

The silicon substrate having 5 or more raised portions may have a higher surface roughness than a typical Si wafer, thereby further reducing reflectance of sunlight. The silicon substrate as described may have an increased contact area with the electrode, thereby providing good properties in terms of contact resistance (Rc) and short-circuit current (Isc).

There are two primary methods to form a nano-texture (or raised portions) on the silicon substrate: wet etching and dry etching. A representative example of wet etching is metal catalyzed chemical etching (MCCE). For example, saw damage caused by diamond sawing may be removed through a saw damage removal (SDR) process, followed by formation of a nano-texture through MCCE. Herein, “MCCE” may include a process of gradually etching a surface of a Si substrate with silver nitrate (AgNO₃), followed by removal of silver nanoparticles, i.e., byproducts. A representative example of dry etching is reactive ion etching (RIE) in which a silicon wafer that has been subjected to SDR is dry-etched using plasma. Here, SF₆/O₂ gas may be used to generate plasma and a SiOF layer used as a mask is removed.

According to some implementations, a nano-texture (or the number of raised portions) of the silicon substrate may be controlled by wet etching.

According to some implementations, the solar cell according may further include an anti-reflection film on the front surface of the silicon substrate 10. A back surface field layer, an anti-reflection film, and the rear electrode 21 may be sequentially formed on the back surface of the silicon substrate 10. The front electrode 23 or the rear electrode 21 may be formed in a bus bar pattern.

Hereinafter, for convenience of explanation, each component of the solar cell will be described on the assumption that the semiconductor substrate 11 is a p-type substrate. However, it should be understood that in some implementations, the semiconductor substrate 11 may be an n-type substrate.

One surface of the p-type substrate 11 may be doped with an n-type dopant to form an n-type emitter 12 to establish a PN junction. The PN junction may be established at an interface between the semiconductor substrate and the emitter. Electrons generated in the PN junction may be collected by the front electrode 23.

The substrate 10 may have a textured structure on the front surface thereof. The textured structure may be formed by surface treatment of the front surface of the substrate 10 using a suitable method such as etching. The textured structure may serve to condense light entering the front surface of the substrate. The textured structure may have a pyramidal shape, a square honeycomb shape, a triangular honeycomb shape, or the like. The textured structure may allow an increased amount of light to reach the PN junction and may reduce reflectance of light, thereby minimizing optical loss.

According to embodiments, the silicon substrate having the textured structure may further be formed with raised portions, thereby further reducing reflectance of sunlight while providing further improved properties in terms of contact resistance (Rc) and short-circuit current (Isc).

The p-type substrate may be formed on the back surface thereof with a back surface field (BSF) layer capable of inducing back surface field (BSF) effects.

The back surface field layer may be formed by doping the back surface of the p-type semiconductor substrate 11 with a high concentration of p-type dopant. The back surface field layer may have a higher doping concentration than the p-type semiconductor substrate 11, resulting in a potential difference between the back surface field layer and the p-type semiconductor substrate 11. Accordingly it may be difficult for electrons generated in the p-type semiconductor substrate 11 to shift towards the back surface of the substrate. Recombination of electrons with metals may be prevented, thereby reducing electron loss. As a result, both open circuit voltage (Voc) and fill factor can be increased, thereby improving solar cell efficiency.

In addition, a first anti-reflection film and/or a second anti-reflection film may be formed on an upper surface of the n-type emitter 12 and on a lower surface of the back surface field layer, respectively.

The first and second anti-reflection films may reduce reflectance of light while increasing absorption of light at a specific wavelength. In addition, the first and second anti-reflection films may enhance contact efficiency with silicon present on the surface of the silicon substrate 10, thereby improving solar cell efficiency. The first and second anti-reflection films may include a material that reflects less light and exhibits electric insulation. Further, the first and second anti-reflection films may have an uneven surface, or may have the same form as that of the textured structure formed on the substrate. In this case, return loss of incident light can be reduced.

The first and second anti-reflection films may include, for example, at least one of an oxide such as aluminum oxide (Al₂O₃), silicon oxide (SiO₂), titanium oxide (TiO₂ or TiO₄), magnesium oxide (MgO), cerium oxide (CeO₂), or a combination thereof; a nitride such as aluminum nitride (AlN), silicon nitride (SiNx), titanium nitride (TiN), or a combination thereof; and an oxynitride including aluminum oxynitride (AlON), silicon oxynitride (SiON), titanium oxynitride (TiON), or a combination thereof. Such first and second anti-reflection films may exhibit further improved anti-reflection efficiency.

The anti-reflection films may be formed, for example, by atomic layer deposition (ALD), vacuum deposition, atmospheric pressure chemical vapor deposition, plasma enhanced chemical vapor deposition, or the like.

In some implementations, the anti-reflection films may be formed of silicon nitride (SiNₓ) or the like by plasma enhanced chemical vapor deposition (PECVD). In some implementations, the anti-reflection films may be formed of aluminum oxide (Al₂O₃) or the like by atomic layer deposition (ALD).

In some implementations, the first anti-reflection film may be formed on the front surface of the silicon substrate 10 and may have a monolayer or multilayer structure.

When the back surface of the p-type semiconductor substrate 11 is doped with boron to form the back surface field layer, the second anti-reflection film may be formed on a lower surface of the back surface field layer. The second anti-reflection film may further increase open circuit voltage.

After formation of the anti-reflection films, the front electrode 23 electrically connected to the n-type emitter layer 12 and the rear electrode 21 electrically connected to the p-type substrate 11 may be formed. The front electrode 23 may allow electrons collected by the n-type emitter to shift thereto. The rear electrode 21 may electrically communicate with the p-type substrate and may serve as a path through which electric current flows.

The front electrode 23 and the rear electrode 21 may be formed of the composition for solar cell electrodes.

For example, the composition for solar cell electrodes may be deposited on the back surface of the PN junction substrate by printing. Then, a preliminary process of preparing the rear electrode may be performed by drying at about 200° C. to about 400° C. for about 10 to about 60 seconds. Further, a preliminary process for preparing the front electrode may be performed by printing the composition for solar cell electrodes on the front surface of the PN junction substrate, followed by drying the printed composition. Then, the front electrode and the rear electrode may be formed by baking at about 400° C. to about 950° C., or, for example, at about 750° C. to about 950° C., for about 30 to about 210 seconds or, for example, about 30 to about 180 seconds.

When the front electrode or the rear electrode according to this embodiment is formed of the composition for solar cell electrodes described below, the silicon substrate may exhibit good adhesion to the electrodes despite having the raised portions, thereby providing further improved properties in terms of contact resistance, serial resistance and the like.

Composition for Solar Cell Electrodes

The composition for solar cell electrodes may include a conductive powder, a glass frit, an organic binder, a surface tension modifier, and a solvent. Each component of the composition for solar cell electrodes will be described in more detail below.

Conductive Powder

The composition for solar cell electrodes may include silver (Ag) powder as the conductive powder. The silver powder may have a nanometer or micrometer-scale particle size. For example, the silver powder may have an average particle diameter of dozens to several hundred nanometers, or an average particle diameter of several to dozens of micrometers. In some implementations, the silver powder may be a mixture of two or more types of silver powder having different particle sizes. The average particle diameter may be measured using, for example, a Model 1064D particle analyzer (CILAS Co., Ltd.) after dispersing the conductive powder in isopropyl alcohol (IPA) at 25° C. for 3 minutes via ultrasonication.

The silver powder may have, for example, a spherical, flake or amorphous particle shape.

The conductive powder may be present in an amount of about 60 wt % to about 95 wt % based on the total weight of the composition for solar cell electrodes. Within this range, the composition may reduce resistance of a solar cell electrode, thereby improving conversion efficiency of a solar cell. In addition, the composition may be easily prepared in paste form. The silver powder may be present in an amount of, for example, about 60 wt % to about 95 wt % based on the total weight of the composition for solar cell electrodes. Within this range, the composition may improve conversion efficiency of a solar cell and may be easily prepared in paste form.

Glass Frit

The glass frit may serve to form silver crystal grains in an emitter region by etching an anti-reflection layer and melting the conductive powder during a baking process of the composition for solar cell electrodes. The glass frit may improve adhesion of the conductive powder to a wafer and may be softened to decrease the baking temperature during the baking process.

The glass frit may include at least one elemental metal of tellurium (Te), lithium (Li), zinc (Zn), bismuth (Bi), lead (Pb), sodium (Na), phosphorus (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B). The glass frit may be formed of an oxide of the at least one elemental metal.

For example, the glass frit may include at least one of a Bi—Te—O glass frit, a Pb—Bi—O glass frit, a Pb—Te—O glass frit, a Te—B—O glass fit, a Te—Ag—O glass frit, a Pb—Si—O glass frit, a Bi—Si—O glass frit, a Te—Zn—O glass frit, a Bi—B—O glass frit, a Pb—B—O glass fit, a Bi—Mo—O glass fit, a Mo—B—O glass frit, and a Te—Si—O glass frit. In this case, a solar cell electrode formed of the composition may exhibit good balance between electrical properties.

The glass frit may be prepared by a suitable method. For example, the glass fit may be prepared by mixing the aforementioned components using a ball mill or a planetary mill, melting the mixture at 900° C. to 1,300° C., and quenching the melted mixture to 25° C., followed by pulverizing the obtained product using a disk mill, a planetary mill or the like. The glass frit may have an average particle diameter (D50) of about 0.1 μm to about 10 μm.

The glass frit may be present in an amount of about 0.1 wt % to about 20 wt %, or, for example, about 0.5 wt % to about 10 wt %, based on the total weight of the composition for solar cell electrodes. Within this range, the glass frit may secure stability of a PN junction under various sheet resistances, minimize resistance, and ultimately improve the efficiency of a solar cell.

Organic Binder

The organic binder resin may be selected from an acrylate resin or a cellulose resin. For example, ethyl cellulose may be used as the organic binder. In addition, the organic binder may include at least one of ethyl hydroxyethyl cellulose, nitrocellulose, a blend of ethyl cellulose and phenol resins, an alkyd resin, a phenol resin, an acrylate ester resin, a xylene resin, a polybutane resin, a polyester resin, a urea resin, a melamine resin, a vinyl acetate resin, wood rosin, a polymethacrylate of an alcohol, polyvinyl butyrate, and polyvinyl acetal.

The organic binder may be present in an amount of about 0.1 wt % to about 15 wt %, or, for example, about 0.1 wt % to about 10 wt % in the composition for solar cell electrodes. Within this range, the organic binder may provide sufficient adhesive strength to a solar cell electrode formed of the composition.

Surface Tension Modifier

The surface tension modifier may serve to control a water contact angle of the composition for solar cell electrodes.

The surface tension modifier may include at least one of a silicone-based additive, an amide-based additive, and a fatty acid-based surfactant. The kind and amount of the surface tension modifier may be adjusted depending on the kinds and amounts of the other components so as to obtain a desired water contact angle of the composition.

The surface tension modifier may be present in an amount of about 0.1 wt % to about 5 wt %, or, for example, about 0.1 wt % to about 4 wt % in the composition for solar cell electrodes. Within this range, the water contact angle of the composition for solar cell electrodes can be easily controlled.

Solvent

The solvent may include, for example, at least one selected from hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, methylethylketone, benzyl alcohol, γ-butyrolactone, ethyl lactate, texanol, and diethylene glycol dibutyl ether. The amount of the solvent may be adjusted depending on the other components so as to obtain a desired water contact angle of the composition. For example, the water contact angle of the composition for solar cell electrodes may be easily controlled using a suitable combination of the surface tension modifier and the solvent.

The solvent may be present in an amount of about 0.1 wt % to about 20 wt %, or, for example, about 0.1 wt % to about 15 wt % in the composition for solar cell electrodes. Within this range, the water contact angle of the composition solar cell electrodes may be easily controlled.

Additive

The composition for solar cell electrodes may further include a suitable additive to enhance flowability, processability and stability, as desired. The additive may include a dispersant, a thixotropic agent, a plasticizer, a viscosity stabilizer, an anti-foaming agent, a pigment, a UV stabilizer, an antioxidant, a coupling agent, or the like. These may be used alone or as a mixture thereof. The additive may be present in an amount of about 0.1 wt % to about 5 wt % based on the total weight of the composition for solar cell electrodes. The content of the additive may be changed, as desired.

The composition for solar cell electrodes may have a water contact angle of about 15° to about 60°. Within this range, the composition may be well deposited on the silicon substrate formed with the raised portions and may have good adhesion to the substrate, thereby further improving electrical properties such as contact resistance and serial resistance.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

As an organic binder, 2.0 wt % of ethylcellulose (STD4, Dow Chemical Company) was sufficiently dissolved in 4.2 wt % of 2,2,4-trimethyl-1,3-pentanediol monoisobutyrate (Texanol, Eastman Chemicals) at 60° C., and then 88.9 wt % of spherical silver powder (AG-4-8, Dowa Hightech Co., Ltd.) having an average particle diameter of 2.0 μm, 3.1 wt % of a Pb—Te—O glass frit having an average particle diameter of 1.0 μm (Tg: 275° C., Tc: 410° C., Tm: 530° C.), 0.5 wt % of a surface tension modifier (KF-96, Shinetsu Chemical Co., Ltd.), 0.5 wt % of a dispersant (BYK102, BYK-chemie), and 0.8 wt % of a thixotropic agent (Thixatrol ST, Elementis Co., Ltd.) were added to the binder solution, followed by mixing and kneading in a 3-roll kneader, thereby preparing a composition for solar cell electrodes. The composition had a water contact angle of 43.5°.

The composition was deposited onto a front surface of a silicon substrate by screen printing in a predetermined pattern, followed by drying in an IR drying furnace. A cell formed according to this procedure was subjected to baking at 600° C. to 900° C. for 30 to 210 seconds in a belt-type baking furnace, thereby fabricating a solar cell.

### Example 2

A solar cell was fabricated in the same manner as in Example 1 except that butyl carbitol acetate (BCA, Dow Chemical Company) was used as a solvent instead of Texanol, such that the composition for solar cell electrodes had a water contact angle of 21.2°.

### Example 3

A solar cell was fabricated in the same manner as in Example 1 except that spherical silver powder (AG-4-100, Dowa Hightech Co., Ltd.) having an average particle diameter of 2.0 μm was used instead of the silver powder (AG-4-8, Dowa Hightech Co., Ltd.), such that the composition for solar cell electrodes had a water contact angle of 57.1°.

### Example 4

A solar cell was fabricated in the same manner as in Example 1 except that 3.1 wt % of a Bi—Te—O glass frit having an average particle diameter of 1.0 μm (Tg: 296° C., Tc: 419° C., Tm: 611° C.) was used instead of the Pb—Te—O glass frit, 0.5 wt % of oleic acid was further used as a surface tension modifier, and 0.3 wt % of the dispersant (BYK102, BYK-chemie) and 0.5 wt % of the thixotropic agent (Thixatrol ST, Elementis Co., Ltd.) were used, such that the composition for solar cell electrodes had a water contact angle of 49.2°.

### Example 5

A solar cell was fabricated in the same manner as in Example 1 except that a silicon substrate formed with 5 raised portions was used.

### Comparative Example 1

A solar cell was fabricated in the same manner as in Example 1 except that terpineol (Sigma-Aldrich Co., Ltd.) was used as a solvent instead of Texanol, such that the composition for solar cell electrodes had a water contact angle of 12.6°.

### Comparative Example 2

A solar cell was fabricated in the same manner as in Example 1 except that 3.1 wt % of a Bi—Te—O glass frit having an average particle diameter of 1.0 μM (Tg: 296° C., Tc: 419° C., Tm: 611° C.) was used instead of the Pb—Te—O glass fit, and 3.2 wt % of Texanol, 2.0 wt % of the surface tension modifier (KF-96, Shinetsu Chemical Co., Ltd.), 0.3 wt % of the dispersant (BYK102, BYK-chemie), and 0.5 wt % of the thixotropic agent (Thixatrol ST, Elementis Co., Ltd.) were used, such that the composition for solar cell electrodes had a water contact angle of 67.2°.

### Comparative Example 3

A solar cell was fabricated in the same manner as in Example 1 except that a silicon substrate formed with 2 raised portions was used.

### Comparative Example 4

A solar cell was fabricated in the same manner as in Example 1 except that a silicon substrate without any raised portion (the number of raised portions: 0) was used.

Property Evaluation

(1) Number of raised portions: The number of raised portions having a height (h) of about 50 nm or more per 5 μm length was measured ten times using an electron microscope image of the cross-section of each of the solar cells fabricated in Examples and Comparative Examples, followed by averaging the values. Results are shown in Table 1.

(2) Water contact angle (°): Water contact angle of each of the compositions for solar cell electrodes prepared in Examples and Comparative Examples was measured through a process in which the composition for solar cell electrodes was applied to a polymer film at room temperature (about 20° C. to about 25° C.) using a squeegee to form a film and then distilled water was dropped onto a surface of the film using a micro syringe, followed by measurement of an angle between the tangent of the liquid at a liquid-solid-gas junction and the surface of the film using a contact angle meter (Phoenix 300 plus, SEO Co., Ltd.). Here, the polymer film was a polyethylene terephthalate (PET) film, without being limited thereto.

(3) Short-circuit current (Isc, A), serial resistance (Rs, mΩ), fill factor (%) and efficiency (%): Each of the compositions for solar cell electrodes prepared in Examples and Comparative Examples was deposited onto a front surface of a wafer by screen printing in a predetermined pattern, followed by drying in an IR drying furnace. Then, an aluminum paste was printed onto a back surface of the wafer and dried in the same manner as above. A cell formed according to this procedure was subjected to drying and baking at 200° C. to 900° C. for 30 to 180 seconds in a belt-type baking furnace, and then evaluated as to short-circuit current (Isc, A), serial resistance (Rs, Ω), fill factor (FF, %) and conversion efficiency (Eff. %) using a solar cell efficiency tester CT-801 (Pasan Co., Ltd.). Results are shown in Table 1.

TABLE 1

| | Number of | | Short-circuit | Serial | | |
|---|---|---|---|---|---|---|
| | raised | Water contact | current | resistance | FF | Eff. |
| | portions | angle (°) | (A) | (Ω) | (%) | (%) |
| Example 1 | 12 | 43.5 | 8.804 | 0.00224 | 79.826 | 18.356 |
| Example 2 | 9 | 21.2 | 8.783 | 0.00218 | 79.923 | 18.344 |
| Example 3 | 18 | 57.1 | 8.830 | 0.00240 | 79.580 | 18.360 |
| Example 4 | 17 | 49.2 | 8.808 | 0.00225 | 79.789 | 18.387 |
| Example 5 | 5 | 43.5 | 8.820 | 0.00229 | 79.637 | 18.344 |
| Comparative | 8 | 12.6 | 8.701 | 0.00287 | 78.570 | 17.968 |
| Example 1 | | | | | | |
| Comparative | 11 | 67.2 | 8.772 | 0.00312 | 77.629 | 18.061 |
| Example 2 | | | | | | |
| Comparative | 2 | 43.5 | 8.717 | 0.00276 | 78.621 | 17.959 |
| Example 3 | | | | | | |
| Comparative | 0 | 43.5 | 8.366 | 0.00716 | 71.526 | 16.087 |
| Example 4 | | | | | | |

As shown in Table 1, it can be seen that the solar cells of Examples 1 to 5 in which the number of raised portions and the water contact angle of the composition fell within the ranges set forth herein had a high short-circuit current and a low serial resistance (Rs), and thus exhibited a high fill factor (FF) and conversion efficiency.

Conversely, the solar cell of Comparative Example 1 exhibited a low short-circuit current due to a low water contact angle (15° or less) and had a high serial resistance (Rs). The solar cell of Comparative Example 2 had a sufficiently high short-circuit current due to high water contact angle (60° or more), but exhibited poor pattern printability, and thus, a high serial resistance (Rs) and low conversion efficiency. In addition, the solar cells of Comparative Examples 3 to 4, in which the number of raised portions of the silicon substrate was less than the range set forth herein, had a low short-circuit current and a high serial resistance (Rs).

By way of summation and review, in order to reduce reflectance of light incident on a solar cell to improve efficiency of the solar cell, a method has been proposed in which a surface of a substrate is textured and/or is formed with an anti-reflection film. However, such method cannot provide sufficient anti-reflection properties. In addition, an electrode prepared by such method may have poor adhesion to the substrate having a textured surface.

Accordingly, a solar cell that can reduce reflection of light incident thereon and improve adhesion of an electrode to a substrate, thereby exhibiting good electrical properties, such as contact resistance, serial resistance, short-circuit current and conversion efficiency, is desirable.

Embodiments provide a solar cell that can reduce reflectance, thereby exhibiting improved conversion efficiency.

Embodiments further provide a solar cell that can improve adhesion of an electrode to a substrate, thereby exhibiting good electrical properties, such as contact resistance, serial resistance and short-circuit current

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A solar cell, comprising:
a silicon substrate and an electrode on the silicon substrate,
wherein the silicon substrate includes at least 5 raised portions having a cross-sectional height (h) of about 50 nm or more per 5 μm length, and
the electrode is formed from a composition for solar cell electrodes having a water contact angle of about 15° to about 60°.

2. The solar cell according as claimed in claim 1, wherein the composition for solar cell electrodes includes:
about 60 wt % to about 95 wt % of a conductive powder;
about 0.1 wt % to about 20 wt % of a glass frit;
about 0.1 wt % to about 15 wt % of an organic binder;
about 0.1 wt % to about 5 wt % of a surface tension modifier; and
about 0.1 wt % to about 20 wt % of a solvent.

3. The solar cell according as claimed in claim 2, wherein the glass frit includes at least one elemental metal of tellurium (Te), lithium (Li), zinc (Zn), bismuth (Bi), lead (Pb), sodium (Na), phosphorus (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

4. The solar cell according as claimed in claim 2, wherein the surface tension modifier includes at least one of a silicone-based additive, an amide-based additive, and a fatty acid-based surfactant.

5. The solar cell according as claimed in claim 2, wherein the solvent includes at least one of hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, methylethylketone, benzyl alcohol, γ-butyrolactone, ethyl lactate, texanol, and diethylene glycol dibutyl ether.

6. The solar cell according as claimed in claim 2, wherein the organic binder includes at least one of ethyl hydroxyethyl cellulose, nitrocellulose, a blend of ethyl cellulose and phenol resins, an alkyd resin, a phenol resin, an acrylate ester resin, a xylene resin, a polybutane resin, a polyester resin, a urea resin, a melamine resin, a vinyl acetate resin, wood rosin, a polymethacrylate of an alcohol, polyvinyl butyrate, and polyvinyl acetal.

7. The solar cell according as claimed in claim 2, wherein the composition for solar cell electrodes further includes at least one additive, the at least one additive including at least one of a dispersant, a thixotropic agent, a plasticizer, a viscosity stabilizer, an anti-foaming agent, a pigment, a UV stabilizer, an antioxidant, and a coupling agent.
